(19) United States
(12) Patent Application Publication
(10) Pub. No.: US 2019/0275658 A1
(43) Pub. Date: Sep. 12, 2019

(54) Handle Support Module

(71) Applicant: Snap-on Incorporated, Kenosha, WI (US)

(72) Inventor: Paul W. Griffin, Kenosha, WI (US)

(73) Assignee: Snap-on Incorporated, Kenosha, WI (US)

(21) Appl. No.: 15/917,086

(22) Filed: Mar. 9, 2018

(51) Int. Cl. B25F 5/02; B25F 5/00

(52) U.S. Cl. CPC B25F 5/02; H02K 7/145; B25F 5/006

(57) ABSTRACT

An electronics module with a housing shaped to conform to the internal shape of a power tool handle. The housing can be made of a metal or a high density polymer to stabilize the handle and enclose electronics within the handle. The module can further include a potting compound provided within openings of the handle to dampen vibrations and resist impact during events that are likely to cause failure at the handle.

### TECHNICAL FIELD OF THE INVENTION

The present application relates generally to electronic modules. More particularly, the present application relates to an electronics module with a housing shaped to the internal contours of a power tool handle.

### BACKGROUND OF THE INVENTION

Structural stability is an important feature for a power tool. Power tools, such as power drills, are often dropped or otherwise handled with little caution. To test the strength of a power tool, so-called “drop tests” are performed where a tool is dropped from a specific height and then it is determined whether the tool cracked or otherwise failed. The results of these drop tests are then used to quantify the structural stability of the power tool.

For many tools, the handle of the tool is the point of failure. This is because the handle is often smaller at the bottom to better fit the ergonomics of a user's hand. By shaping the handle this way, however, the power tool sacrifices structural stability at the bottom of the handle to provide the ergonomic benefit. Most power tools also include batteries connected to the bottom of the handle, meaning the inside of the handle includes electronics connecting, for example, the battery to the motor and trigger.

### SUMMARY OF THE INVENTION

The present invention relates broadly to an electronics module with a housing that is shaped to conform to the internal geometry of the handle of the power tool. The housing can be made of a strong material such as metal or a high density polymer so as to provide additional structural stability to the power tool handle while at the same time enclosing the electronics. The electronics can further be submerged by a potting compound to provide additional vibrational dampening and impact resistance when the tool is dropped.

In particular, the present invention includes a tool having a motor, a battery that provides power to the motor, electrical components between the battery and the motor, and a housing enclosing the electrical components. The housing has an external geometry and an internal opening adjacent the electrical components, with potting compound disposed within the opening. The tool further includes a handle having an internal geometry, where the external geometry of the housing generally conforms to the internal geometry of the handle.

Further disclosed is an electronics module for a tool having a motor, a battery that provides power to the motor, and electrical components between the battery and the motor, and a handle having an internal geometry. The electronics module includes a housing enclosing the electrical components. The housing has an external geometry and an internal opening adjacent the electrical components, with potting compound disposed within the opening. The external geometry of the housing generally conforms to the internal geometry of the handle.

### BRIEF DESCRIPTION OF THE DRAWINGS

For the purpose of facilitating an understanding of the subject matter sought to be protected, there are illustrated in the accompanying drawings embodiments thereof, from an inspection of which, when considered in connection with the following description, the subject matter sought to be protected, its construction and operation, and many of its advantages should be readily understood and appreciated.

FIG. 1 is a side sectional view of a tool according to at least some embodiments of the present invention.

FIG. 2 is a side partially exploded view of an electronics control module according to at least some embodiments of the present invention.

FIG. 3 is a bottom sectional view of a handle of a tool according to at least some embodiments of the present invention.

FIG. 4 is a partial side sectional view of a handle of a tool according to at least some embodiments of the present invention.

### DETAILED DESCRIPTION OF THE EMBODIMENTS

While this invention is susceptible of embodiments in many different forms, there is shown in the drawings, and will herein be described in detail, a preferred embodiment of the invention with the understanding that the present disclosure is to be considered as an exemplification of the principles of the invention and is not intended to limit the broad aspect of the invention to embodiments illustrated. As used herein, the term “present invention” is not intended to limit the scope of the claimed invention and is instead a term used to discuss exemplary embodiments of the invention for explanatory purposes only.

The present invention broadly comprises an electronics module with a housing having a shape that generally conforms to the internal geometry of a handle of a tool. In some embodiments, the housing is made of a strong material such as metal or a high density polymer to stabilize the handle and enclose electronics within the handle. The module can further include a potting compound provided within openings of the handle to provide additional vibrational dampening and impact resistance.

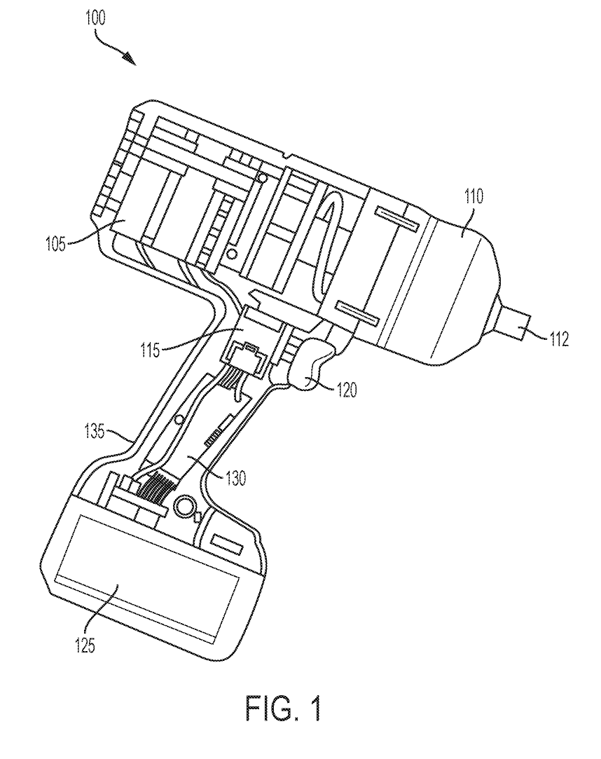

As shown, FIG. 1 illustrates a tool 100 having a motor 105 that controls mechanical components 110 such as a gear train, that eventually provides torque to a working end 112 of the tool 100. The tool 100 further includes a switch 115 that switches on and off power to the motor 105 based on selective actuation of a trigger 120. The power delivered to the motor 105 originates in a battery 125 that is coupled to the switch 115 by an electronics module 130. The electronics module 130 can be located within a handle 135 of the tool 100 and, as discussed below in more detail, provide structural stability to the handle 135.

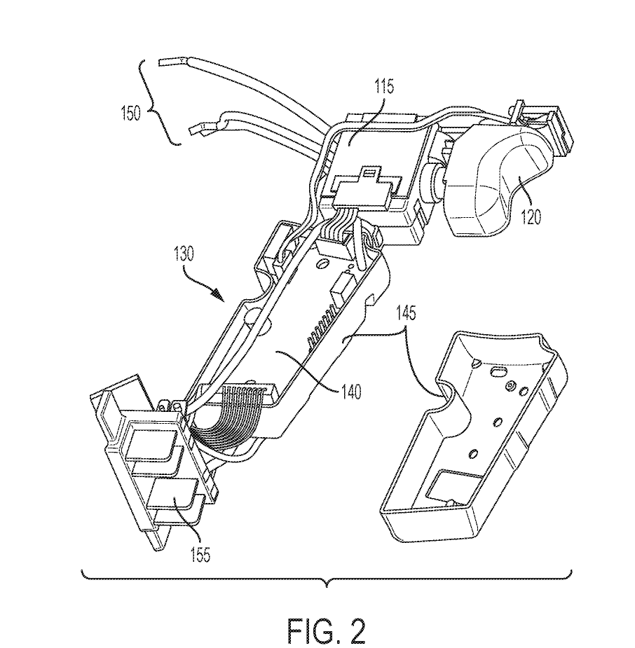

FIG. 2 illustrates the electronics module 130 in partially exploded form. As shown, the electronics module 130 can include electrical components 140, for example, a circuit board that connects the battery 125 to the trigger 120 and switch 115. The electrical components 140 can be enclosed within a housing 145. The housing 145 can be made of a reinforcing material such as metal or a high density polymer, and can further be shaped to contour to the internal geometry of the handle 135. For example, the handle 135 can have an internal geometry, the housing 145 can have an external geometry, and the external geometry of the housing 145 can generally conform to the internal geometry of the handle 135. In this manner, the housing 145 can provide structural stability to a part of the tool 100, the handle 135, that has shown in drop tests to fail more often than other parts of the tool 100.

The housing 145 can be a typical clamshell housing, as shown, or can be any other housing or enclosure that encases the electrical components 140. In an embodiment, the housing 145 can be opened (similar to the clamshell housing shown in FIG. 2) for maintenance or repair of the components inside the housing 145. As shown in FIG. 2, the housing 145 can be coupled to motor connection wires 150 at one end (via the switch 115 and/or the trigger 120, in some embodiments) and can be coupled to battery connection terminals 155 at the other end. The matter connection terminals 155 can couple to the battery 125 to receive power from the battery and distribute it to the electrical components 140, and the motor connection wires 150 can then transmit the power to the motor 105.

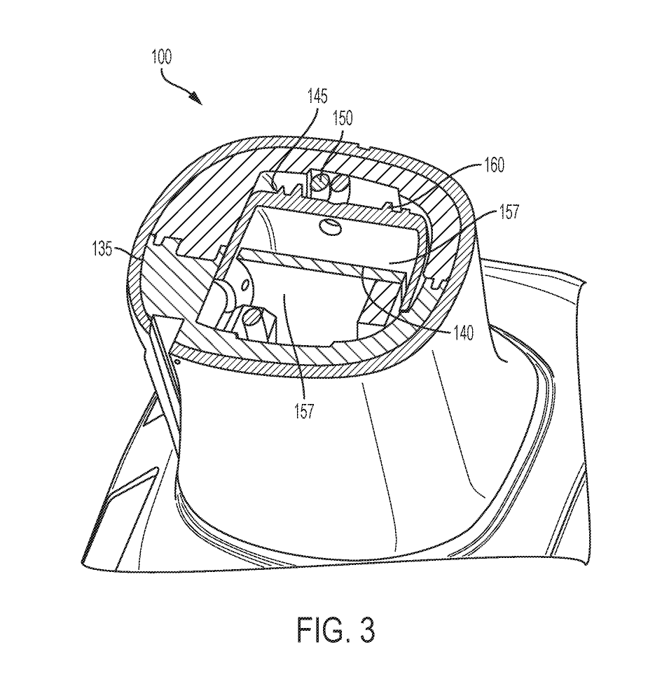

FIG. 3 illustrates a bottom sectional view of a handle 135 according to at least some embodiments of the present invention. As shown, the handle 135 can include openings 157 on both sides of the electrical component 140. In some embodiments, potting compound can be placed within these openings 157 to improve impact resistance or vibrational dampening during, for example, a drop of the tool 100. The potting compound can submerge the electrical components 140 within the housing 145 such that the housing 145 and electronics module 130 act as an independent, enclosed component with improved impact resistance and vibrational dampening.

The handle 135 can also include heat sink fins 160 extending external to the housing 145 from the housing 145 and within an open area of the handle 135. In some embodiments, the heat sink fins 160 are integral with the housing 145 and the housing 145 contacts the electrical components 140 or is thermally coupled to the electrical components 140 to dissipate heat from the electrical components 140.

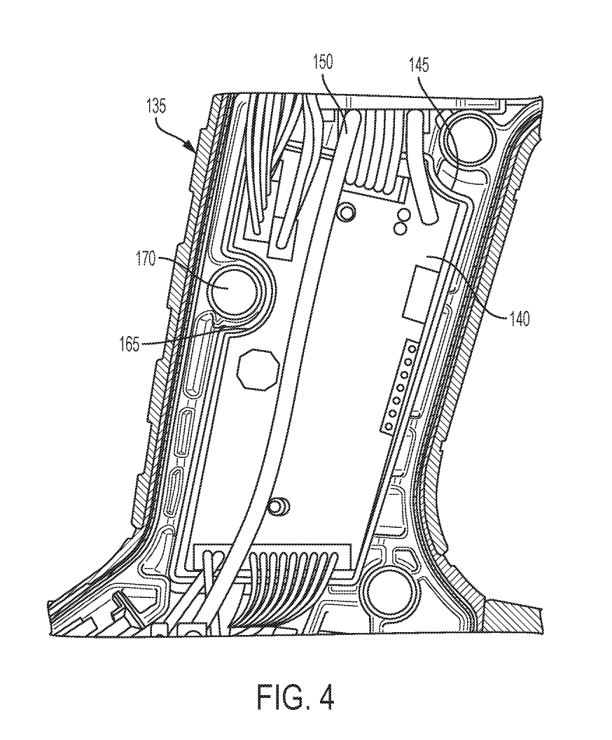

As shown in FIG. 4, the handle 135 can include a curve 165 in the housing 145 and a corresponding screw boss 170 that can fit within the curve 165. In this manner, the curve 165 and the screw boss 170 can be firmly positioned next to one another for ease of assembling the handle 135 with the electrical components 140. For example, a user can insert the curve 165 portion of the housing into the internal area of the handle 135, align the curve 165 with the screw boss 170, and fasten the handle 135 together thereafter. Any other manner of coupling the handle 135 together to enclose the electronics module 130 can be implemented without departing from the spirit and scope of the present invention.

As discussed herein, the housing 145 may be made of metal or a high density polymer. However, the housing 145 may be made of any material that provides increased protection to the electrical components 140 and that provides increased structural stability to the handle 135. The housing 145 may be any metallic, polymeric, or composite material that provides such benefit.

As used herein, the term “coupled” and its functional equivalents are not intended to necessarily be limited to direct, mechanical coupling of two or more components. Instead, the term “coupled” and its functional equivalents are intended to mean any direct or indirect mechanical, electrical, or chemical connection between two or more objects, features, work pieces, and/or environmental matter. “Coupled” is also intended to mean, in some examples, one object being integral with another object.

The matter set forth in the foregoing description and accompanying drawings is offered by way of illustration only and not as a limitation. While particular embodiments have been shown and described, it will be apparent to those skilled in the art that changes and modifications may be made without departing from the broader aspects of the inventors' contribution. The actual scope of the protection sought is intended to be defined in the following claims when viewed in their proper perspective based on the prior art.

What is claimed is:

1. A tool comprising:
a motor;
a battery that provides power to the motor;
electrical components between the battery and the motor;
a housing enclosing the electrical components, the housing having an external geometry and an internal opening adjacent the electrical components; and
a handle having an internal geometry,
wherein the external geometry of the housing generally conforms to the internal geometry of the handle.

2. The tool of claim 1, further comprising motor connection wires extending from the housing and coupled to the motor.

3. The tool of claim 1, further comprising battery connection terminals coupled to the battery and located external to the housing.

4. The tool of claim 1, further comprising heat dissipating fins disposed on the housing and extending into an open area of the handle.

5. The tool of claim 4, wherein the heat dissipating fins are integral with the housing.

6. The tool of claim 5, wherein the housing is thermally coupled to the electrical components to dissipate heat from the electrical components to the heat dissipating fins.

7. The tool of claim 6, wherein the housing is directly connected to the electrical components.

8. The tool of claim 1, wherein the housing includes a curve and the handle includes a screw boss having a shape complementary to the curve such that the housing fits within the handle at the screw boss and curve interface.

9. The tool of claim 1, further comprising potting compound disposed within the opening.

10. An electronics module for a tool having a motor, a battery that provides power to the motor, and electrical components between the battery and the motor, and a handle having an internal geometry, the electronics module comprising:
a housing enclosing the electrical components, the housing having an external geometry and an internal opening adjacent the electrical components; and
wherein the external geometry of the housing generally conforms to the internal geometry of the handle.

11. The electronics module of claim 10, further comprising heat dissipating fins disposed on the housing and extending into an open area of the handle.

12. The electronics module of claim 11, wherein the heat dissipating fins are integral with the housing.

13. The electronics module of claim 12, wherein the housing is thermally coupled to the electrical components to dissipate heat from the electrical components to the heat dissipating fins.

14. The electronics module of claim 13, wherein the housing is directly connected to the electrical components.

15. The electronics module of claim 10, wherein the housing includes a curve and the handle includes a screw boss having a shape complementary to the curve such that the housing fits within the handle at the screw boss and curve interface.

16. The electronics module of claim 10, further comprising potting compound disposed within the internal opening.
